(19) United States
(12) Patent Application Publication
(10) Pub. No.: US 2015/0194554 A1
(43) Pub. Date: Jul. 9, 2015

(54) STRUCTURE OF CONCENTRATING SOLAR CELL MODULE WITH REDUCED HEIGHT

(71) Applicant: ATOMIC ENERGY COUNCIL-INSTITUTE OF NUCLEAR ENERGY RESEARCH, Taoyuan County (TW)

(72) Inventors: YI-PING LIANG, TAOYUAN COUNTY (TW); YI-YA HUANG, TAOYUAN COUNTY (TW); HWEN-FEN HONG, TAOYUAN COUNTY (TW)

(73) Assignee: ATOMIC ENERGY COUNCIL-INSTITUTE OF NUCLEAR ENERGY RESEARCH, Taoyuan County (TW)

(21) Appl. No.: 14/148,957

(22) Filed: Jan. 7, 2014

(51) Int. Cl. H01L 31/052

(52) U.S. Cl. CPC H01L 31/052

(57) ABSTRACT

The present invention relates to a structure of concentrating solar cell module with reduced height, which includes multiple partitions and reflection mirrors. The solar cell receiver is attach to a surface of the partition and rotated by 90 degrees. After the reflection leans against a surface of another partition, the light concentrated by the concentrating lens can be redirected from vertical incidence to horizontal incidence. Then the redirected light is focused at the 90-degree rotated solar cell receiver for performing energy conversion. This structure avoids the limitation of the concentrating solar cell module by the focal distance of the concentrating lens. Thereby, the height of the module is reduced substantially; the volume of the module becomes thinner and the weight thereof becomes lighter and thus facilitating installation and transportation.

### FIELD OF THE INVENTION

The present invention relates generally to a structure of concentrating solar cell module, and particularly to a structure of concentrating solar cell module with reduced height that uses a reflection mirror and redirects the light concentrated by the concentrating lens to a solar cell receiver in the horizontal direction before the light reaches the focal point in the vertical direction. Thereby, the height of the module is no more limited by the focal distance of the concentrating lens.

### BACKGROUND OF THE INVENTION

With the rapid development of industries, the issues of gradual exhaustion of petrochemical fuels, the greenhouse effect, and gas exhaust appeal global attention increasingly. The stability of energy supply has become a major subject in the world. Compared with traditional coal, natural gas, or nuclear power generation, solar cells do not consume non-renewable resources. Instead, they make use of the photoelectric effect to convert solar energy into electric energy directly, and thus producing no green-house gases, such as carbon diode, oxynitrides, and oxysulfides, and pollutant gases. In addition, they provide a safe and independent power source by reducing the reliance on petrochemical fuels.

Regarding to renewable power generating systems, in addition to the advantages of environmental protection and ease of installation, thanks to the maturity of commercialization as well as the planned promotion of countries, solar energy has become the major choice of distributed power system in advanced countries.

Concentrating solar cell modules use III-V chemical materials for fabricating solar cells. Solar cells are first fixed to a substrate. Then focusing devices such as concentrating lenses are used together to form a module. The module enables the incident sunlight to be concentrated in a high multiple at the solar cells. Meanwhile, a sun tracker is used for ensuring light illumination. The overall power generating system of concentrating solar cells can reach approximately 30% of photoelectric conversion efficiency.

Please refer to FIG. 1, which shows a structural schematic diagram of the concentrating solar cell module according to the prior art, where a solar cell receiver 3 is disposed on a substrate 1 composed of a cell substrate 31, a solar cell 32, and a secondary concentrating device 33. Under the illumination of the sun S, a concentrating lens 5 concentrates the sunlight, which is thus focused at the solar cell receiver 3. Accordingly, it is known that the thickness of the concentrating solar cell module according to the prior art is limited by the focal distance of the concentrating lens 5.

Because the height of concentrating solar cell modules is limited by the focal distance of the concentrating lens, the volume thereof becomes very huge, which increases the costs of materials and results in difficulties in transportation as well as high possibilities of damages due to bumps during transportation. In addition, it also retards reduction in weight of the modules, which leads to the requirement of maintaining high strength in the structure of the supporting frames of the tracker. With the additional difficulty in assembling, the costs are also influenced.

The solutions according to the prior art are quite limited. One method is to use materials having greater refractive index to manufacture the concentrating lens; another is to use a concentrating lens having a greater radius of curvature for shortening the focal distance. No matter which of the above methods is adopted, the phenomena of chromatic dispersion become severe; the focused light spot is expanded and uneasy to be focus at one point. Thereby, the angular tolerance of the modules is reduced. In addition, the above methods also reduce the transmissivity of lenses and thus lowering the efficiency of the modules.

Accordingly, the present provides a structure for reducing the volume of the concentrating solar cell module while maintaining the energy conversion efficiency.

### SUMMARY

An objective of the present invention is to provide a structure of solar cell module with reduced height, which uses a reflection mirror to reflect the sunlight concentrated by the concentrating lens to the side of the concentrating solar cell module before the sunlight is focused at the solar cell. Thereby, the solar cell receiver disposed on the side of the concentrating solar cell module can receive the light concentrated by the concentrating lens, and thus maintaining the energy conversion efficiency of the overall structure as the vertical height of the concentrating solar cell module is reduced.

Another objective of the present invention is to provide a structure of solar cell module with reduced height, which has multiple partitions perpendicular to the substrate, so that the solar cell receiver can receive the sunlight reflected by the reflection mirror to the side of the concentrating solar cell module when the solar cell receiver is attach to the partitions.

Still another objective of the present invention is to provide a structure of solar cell module with reduced height, in which the solar cell receiver is disposed on a surface of its multiple partitions. The other surface thereof can be used as the supporting structure for disposing the reflection mirror. Thereby, modularization design can be implemented.

A further objective of the present invention is to provide a structure of solar cell module with reduced height, which can reduce the distance between the concentrating lens and the substrate and thus reducing the volume of the overall solar cell module and facilitating its transportation and installation. Thereby, the costs of transporting the modules and constructing the system are reduced.

A still further objective of the present invention is to provide a structure of solar cell module with reduced height, which can select the concentrating lenses having longer focal distances flexibly for reducing the influence of chromatic dispersion on energy conversion efficiency.

For achieving the objectives described above, the present invention discloses a structure of concentrating solar cell module with reduced height, which comprises a substrate, a first partition, a second partition, at least a solar cell receiver, at least a reflection mirror, and at least a concentrating lens. The first and second partitions are disposed on the substrate. The solar cell receiver is disposed on a surface of the first partition. The reflection mirror is disposed on the substrate, forming a tilt angle between the substrate, leaning against the second partition, and reflecting the sunlight to the surface of the solar cell receiver. The concentrating lens is located above the reflection mirror and concentrating the sunlight and illuminating on the surface of the reflection mirror. The focal distance of the concentrating lens is greater than the distance between the concentrating lens and the substrate. According to the design of the structure, the present invention reduced the height of the concentrating solar cell module to the value smaller than the focal distance of the concentrating lens. Thereby, the volume of the module is shrunk. In addition, the problem of chromatic dispersion can be solved by selecting the concentrating lens having longer focal distances while maintaining the volume of the module. Accordingly, the power generating efficiency is improved effectively.

### BRIEF DESCRIPTION OF THE DRAWINGS

FIG. 1 shows a structural schematic diagram according to the prior art;

FIG. 2 shows a structural schematic diagram of the flat reflection mirror according to a preferred embodiment of the present invention;

FIG. 3 shows a structural schematic diagram of matrix arrangement according to a preferred embodiment of the present invention;

FIG. 4 shows a structural schematic diagram of the partition of right triangular prism according to another preferred embodiment of the present invention;

FIG. 5A shows a structural schematic diagram of the partition of right triangular prism according to the present invention;

FIG. 5B shows a structural schematic diagram of the partition of hollow right triangular prism according to the present invention;

FIG. 6 shows a structural schematic diagram of having only a single solar cell receiver according to a preferred embodiment of the present invention; and

FIG. 7 shows a structural schematic diagram of the curved-surface reflection mirror according to another preferred embodiment of the present invention.

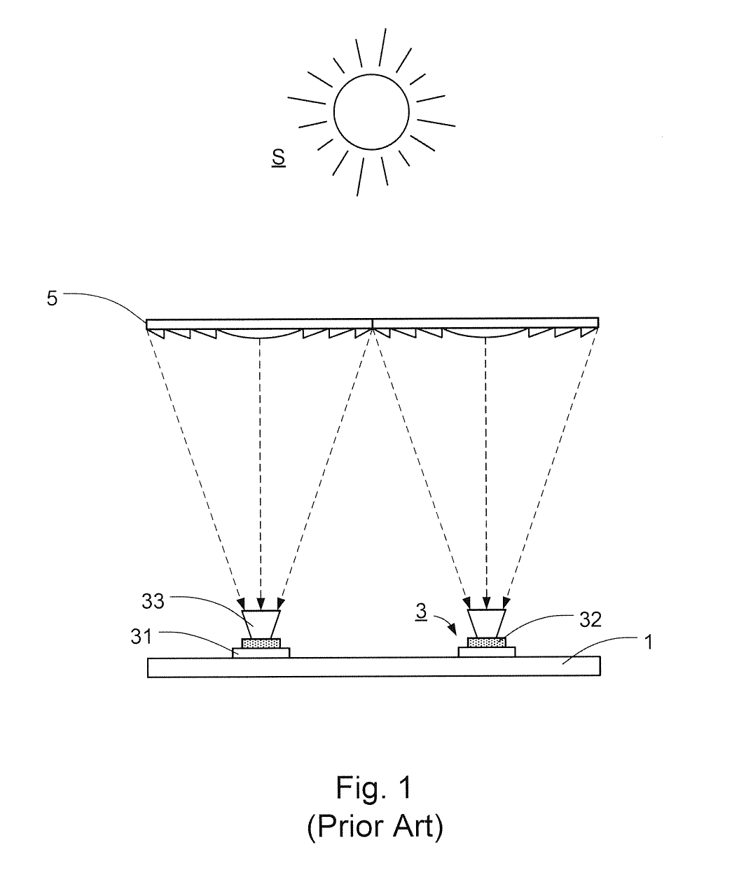

### DETAILED DESCRIPTION

In order to make the structure and characteristics as well as the effectiveness of the present invention to be further understood and recognized, the detailed description of the present invention is provided as follows along with embodiments and accompanying figures.

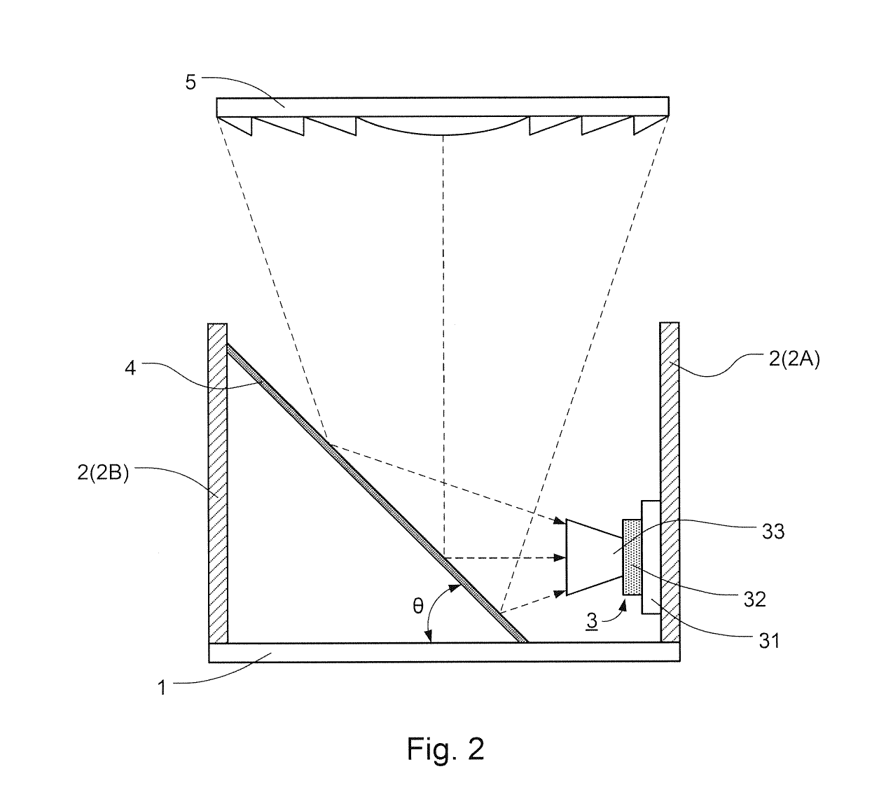

First, please refer to FIG. 2, which shows a structural schematic diagram of the present invention. As shown in the figure, the structure of concentrating solar cell module with reduced height according to the present invention comprises a substrate 1, two partitions 2, a solar cell receiver 3, a reflection mirror 4, and a concentrating mirror 5. The partitions 2 are disposed on and perpendicular to the substrate 1 and including a first partition 2A and a second partition 2B. The solar cell receiver 3 is disposed on a surface of the first partition 2A and perpendicular to the substrate 1. The reflection mirror 4 is disposed on the substrate 1 and leaning against the second partition 2B. Besides, the concentrating lens 5 is located above the reflection mirror 4.

The partitions 2 described above are disposed on and perpendicular to the substrate 1, so that the solar cell receiver 3 is perpendicular to the substrate 1 because the solar cell receive 3 is disposed on a surface of the partition 2. This is an embodiment enabling the sunlight reflected by the reflection mirror 4 to be received by the solar cell receiver 3. In other words, by complying with the optical principles of design, the partitions 2 are not limited to be vertical. It is allowed once the solar cell receiver 3 can receive the sunlight reflected by the reflection mirror 4.

In the parts of the structure according to the present invention, the substrate 1 is a base for carrying every object and made of materials having high thermal conductivity. Thereby, the heat generated by the concentrating solar cell can be dissipated for maintaining the energy conversion efficiency and extending its lifetime. Considering that the concentrating solar cell will be used with a sun tracking system and disposed on a frame, the preferred choice for the material of the substrate 1 is, but not limited to, aluminum due to its light weight and low cost.

The two partitions 2 are disposed on the substrate 1, as the first and second partitions 2A, 2B shown in the figure. The materials of the partitions 2 also have high thermal conductivity and can be selected to be the same material of the substrate 1. Alternatively, the partitions 2 and the substrate 1 can be further formed integrally using simple metal manufacturing technology. These two partitions 2 partition a space on the substrate 1 for accommodating other devices.

According to the present invention, the space partitioned by any two partitions 2 can be regarded as the smallest unit in the power generating matrix of the concentrating solar cell module. In this space, there is the solar cell receiver 3, which is disposed on a surface of one of the partitions 2 and perpendicular to the substrate 1. It can receive the incident focused light in the horizontal direction, which is completely different from receiving the incident focused light in the vertical direction according to the prior art.

The solar cell receiver 3 comprises a cell substrate 31 and a secondary concentrating device 33. The cell substrate 31 is disposed on and attached to the surface of the partition 2. The secondary concentrating device 33 is disposed on the solar cell 32. The above structure is the normal design of a general concentrating solar cell receiver. After the concentrated sunlight reaches the solar cell 32, energy conversion will occur for generating electric energy.

Another important device in the space partitioned by any two partitions 2 is the reflection mirror 4. The reflection mirror 4 is disposed on the substrate 1 at a tilt angle θ, leaning against the other partition 2, and reflecting the sunlight to the surface of the solar cell receiver 3. The preferred tile angle θ is 45 degrees, which makes the vertical incident sunlight illuminate the solar cell receiver 3 horizontally and relatively more directly. The tilt angle θ can be extended to the range between 40 and 50 degrees. Nonetheless, this arrangement leads to difficulty in mastering the proper height for disposing the solar cell receiver 3 and an increase of manufacturing cost.

The device above the reflection mirror 4 is the concentrating lens 5, which first concentrates the sunlight and illuminate on the surface of the reflection mirror 4. Then the reflection mirror 4 reflects the light to the solar cell receiver 3 and complete transmission of the solar energy. Considering the requirements of costs, volume, and weight, the concentrating lens 5 can be a Fresnel lens.

By using the reflection mirror 4 and the concentrating lens 5 together, originally, the sunlight will be focused at the solar cell receiver 3 directly after the concentration of the concentrating lens 5. Hence, the focal distance of the concentrating lens 5 is approximately the distance between the concentrating lens 5 and the substrate 1. After adding the reflection mirror 4 according to the present invention, the sunlight will be reflected before it is concentrated at the focal point of the concentrating lens 5. The traveling direction of the sunlight will be changed from the vertical direction to the horizontal direction and finally the sunlight will be focused at the solar cell receiver 3. By changing the light path, the focal distance of the concentrating lens 5 will be greater than the distance between the concentrating lens 5 and the substrate 1. In other words, the height of the concentrating solar cell module in the vertical direction can be shrunk substantially.

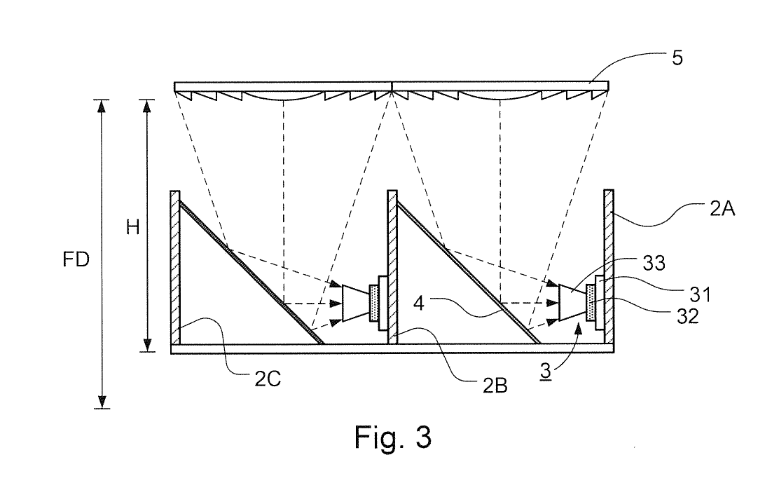

Please refer to FIG. 3. The sunlight is focused by the concentrating lens 5 and travels towards the focal point. The distance between the focal point and the concentrating lens 5 is just the focal distance FD. Thanks to the reflection function of the reflection mirror 4, the height H from the substrate 1 of the concentrating solar cell module to the concentrating lens 5 only needs to be kept much smaller than the focal distance FD. Namely, the focal distance of the concentrating lens 5 is much larger than the distance between the concentrating lens 5 and the substrate 1. According to experiments and tests, the reduction ratio of the height of the concentrating solar cell module is shown in Table 1:

TABLE 1

| | Focal Distance of | | | |
|---|---|---|---|---|
| | Concentrating | Original Height | Reduced Height | Reduction |
| No. | Lens FD (cm) | H (cm) | H (cm) | Ratio |
| A | 20 | 20 | 15 | 25% |
| B | 17.5 | 17.5 | 13 | 28% |
| C | 12.5 | 12.5 | 8 | 35% |

The structure proposed according to the present invention facilitates shrinkage of the concentrating solar cell module. The shrinkage in volume helps transportation and installation of the module as well as reducing the costs for transporting the modules and setting up the system. Because the method for shortening the focal distance according to the present invention is reflection, the chromatic dispersion of the sunlight and the transmissivity of the lens will not be influenced. Accordingly, the original energy conversion efficiency will not be affected.

Moreover, according to the present invention, the concentrating lens 5 in the structure can have lower refractivity or smaller radius of curvature for reducing the chromatic dispersion as the sunlight is focused by the concentrating lens 5. In addition, the angular tolerance of the modules can be enhanced for maintaining the operating efficiency of the modules.

Please refer again to FIG. 3, which shows a structural schematic diagram of the matrix-type concentrating solar cell module according to a preferred embodiment of the present invention. As shown in the figure, the structure of the matrix-type concentrating solar cell module adopts multiple partitions 2 (the first partition 2A, the second partition 2B, and the third partition 2C) parallel with each other and disposed on and perpendicular to the substrate 1. Between two spaces partitioned by the partitions 2, it is not required to use two partitions 2 attached to each other. In stead, only one partition 2 is required. Both surfaces of a partition 2 can be used for supporting the reflection mirror 4 and attaching the solar cell receiver 3, respectively. Namely, the partitions 2 in the structure are shared. As shown in the figure, a plurality of solar cell receivers 3 are disposed on a surface of the first partition 2A and a surface of the second partition 2B, respectively. On the other hand, a plurality of reflection mirror form the tilt angle θ with the substrate 1, lean against the other surface of the second partition 2B and the other surface of the third partition 2C, and reflect the sunlight to the surfaces of the solar cell receivers 3, respectively. In other words, in the matrix-type concentrating solar cell module, the required number of partitions 2 is the number of the solar cell receivers 3, the reflection mirrors 4, or the concentrating lenses 5 plus one for constructing a complete power generating matrix.

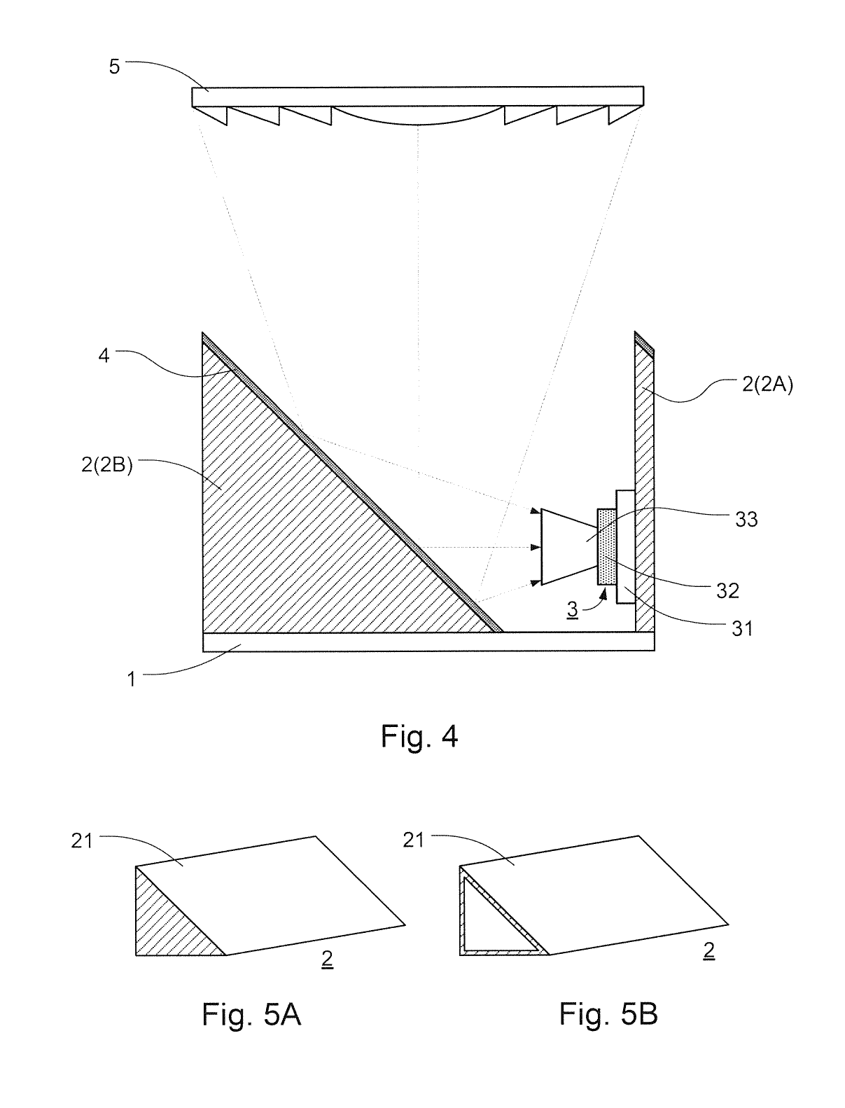

FIGS. 4, 5A, and 5B show another preferred embodiment of the present invention. Here, the adopted second partition 2B is a right triangular prism (the first partition 2A to the right is shown only partially in the figures). Thereby, the second partition 2B has a sloped surface 21 for the reflection mirror 4 to attach completely to. Then, the tile angle θ of the reflection mirror 4 is just the angle between the sloped surface 21 and the substrate 1. According to the present embodiment, the accuracy of the tilt angle θ can be controlled more easily in the manufacturing process. Furthermore, when the reflection mirror 4 reflects the sunlight, the generated heat can be absorbed by the partition and thus improving heat dissipating effect. If the adopted partition of right triangular prism is hollow, the weight of the overall module can be further reduced and hence easing the loading of the frame.

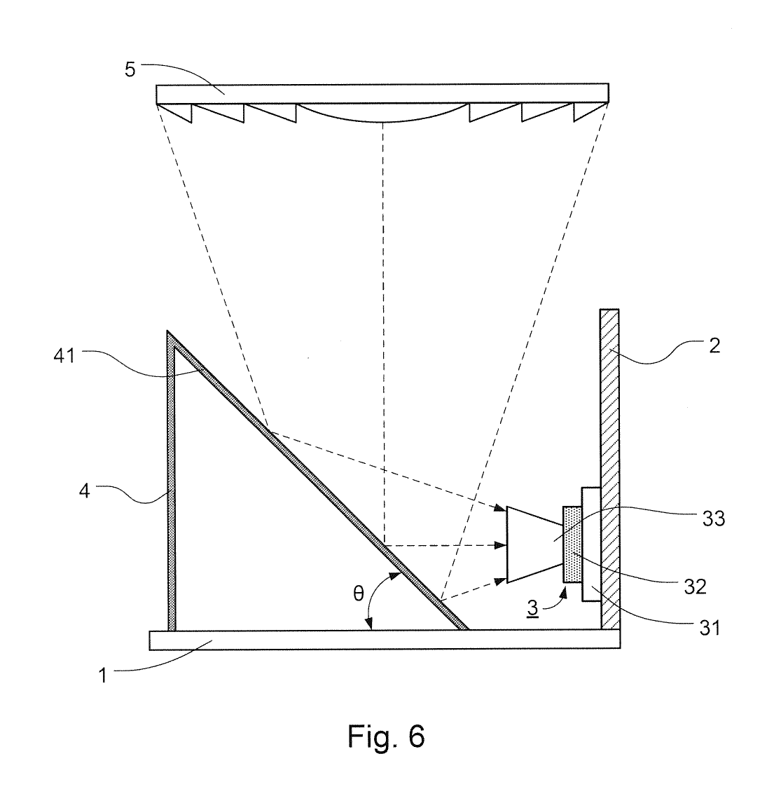

If, instead of manufacturing the matrix-type concentrating solar cell module, a concentrating solar cell module having only a single solar cell receiver 3 is to be prepared, it is not necessary to have two partitions 2 in the structure. As shown in FIG. 6, only a partition 2 suffices for disposing the solar cell receiver 3. In this case, the reflection mirror 4 is disposed on the substrate 1 and is supported by itself. As long as a reflection surface 41 of the reflection mirror 4 form a tile angle θ with the substrate 1, the sunlight can be reflected to the surface of the solar cell receiver 3.

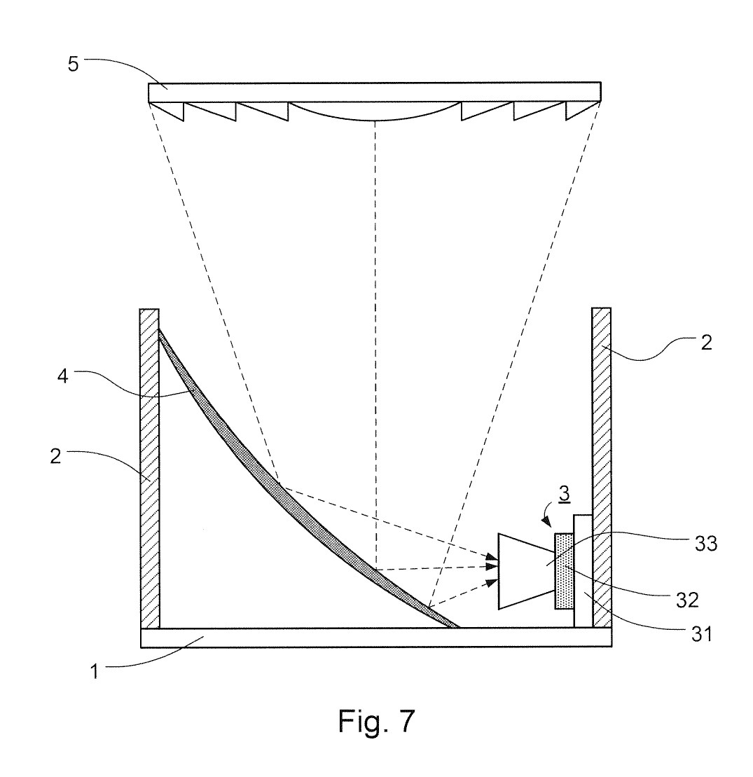

At last, please refer to FIG. 7, which shows still another preferred embodiment of the present invention. In this embodiment, unlike the flat mirror in the previous embodiment, the adopted reflection mirror 4 is a curved-surface mirror. Then, the attachment location of the solar cell receiver 3 on the partition 2 should be adjusted according to the reflection focal point of the curved-surface mirror for achieving the purpose of reducing the height of the concentrating solar cell module.

To sum up, the present invention discloses in detail a structure of concentrating solar cell module with reduced height. Based on the characteristics of the structure, after adding the partition and the reflection mirror, the light concentrated by the concentrating lens is redirected from vertical incidence to horizontal incidence. The solar cell receiver is rotated by 90 degrees and attached to the partition. Then the sunlight is focused at the rotated solar cell receiver after being reflected, substantially reducing the height of the concentrating solar cell module and thus thinning the size and lowering the weight thereof. By maintaining the performance and reducing the cost, the present invention undoubtedly provides a structure of concentrating solar cell with reduced height having enormous practical industrial values.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A structure of concentrating solar cell module with reduced height, comprising:
a substrate;
a first partition and a second partition, disposed on and perpendicular to said substrate, respectively;
at least a solar cell receiver, disposed on a surface of said first partition;
at least a reflection mirror, disposed on said substrate, forming a tilt angle with said substrate, leaning against said second partition, and reflecting the sunlight to the surface of said solar cell receiver; and
at least a concentrating lens, located above said reflection mirror, and concentrating the sunlight and illuminating the surface of said reflection light;
where the focal distance of said concentrating lens is greater than the distance
between said concentrating lens and said substrate.

2. The structure of claim 1, wherein said solar cell receiver comprises:
a cell substrate, disposed on said surface of said first partition;
a solar cell, disposed on said cell substrate; and
a secondary concentrating device, disposed on said solar cell.

3. The structure of claim 1, wherein said solar cell receiver is perpendicular to said substrate.

4. The structure of claim 1, wherein said reflection mirror is a flat mirror.

5. The structure of claim 1, wherein said reflection mirror is a curved-surface mirror.

6. The structure of claim 1, wherein said concentrating lens is a Fresnel lens.

7. The structure of claim 1, wherein said tilt angle is between 40 and 50 degrees.

8. The structure of claim 1, wherein said second partition is a right triangular prism and said reflection mirror is further attached to a sloped surface of said second partition.

9. The structure of claim 8, wherein said second partition is a hollow right triangular prism.

10. A structure of concentrating solar cell module with reduced height, comprising:
a substrate;
a first partition, a second partition, and a third partition, disposed on and perpendicular to said substrate, respectively;
a plurality of solar cell receivers, disposed on a surface of said first partition and a surface of said second partition, respectively;
a plurality of reflection mirrors, disposed on said substrate, forming a tilt angle with said substrate, leaning against the other surfaces of said second partition and said third partition, respectively, and reflecting the sunlight to the surfaces of said solar cell receivers; and
a plurality of concentrating lenses, located above said plurality of reflection mirrors, respectively, and concentrating the sunlight and illuminating the surfaces of said plurality of reflection light;
where the focal distances of said plurality of concentrating lenses are greater than the distances between said plurality of concentrating lenses and said substrate.
